(19) United States
(12) Patent Application Publication
(10) Pub. No.: US 2011/0084684 A1
(43) Pub. Date: Apr. 14, 2011

(54) SWITCHING OF RESISTOR EPI BIASING FOR REVERSED RESISTOR CONNECTION IN OFFSET ELEMENT CANCELLATION SYSTEM

(75) Inventors: Adrian Yu Chien HOI, Singapore (SG); Sharon May Yen KHOO, Singapore (SG); Zhan Quan QUEK, Singapore (SG); Tech Heng LIM, Singapore (SG); Jerry Galanga ADVINCULA, Singapore (SG)

(73) Assignees: PANASONIC CORPORATION, Osaka (JP); PANASONIC SEMICONDUCTOR ASIA PTE., LTD., Singapore (SG)

(21) Appl. No.: 12/578,872

(22) Filed: Oct. 14, 2009

(51) Int. Cl. H03H 1/00

(52) U.S. Cl. 323/369

(57) ABSTRACT

A method of improving voltage detection accuracy and precision by employing a switchable resistor epi bias design, which consists of switches to control connection of resistor epi bias. By constantly maintaining the resistor epi bias to its own resistor terminal bias via switches, higher accuracy detection than conventional resistor bias method can be achieved.

### BACKGROUND OF THE INVENTION

The present invention relates to a voltage detection circuit that detects an input voltage in first and second periods to average by using a switch circuit and a sample and hold circuit.

An example of an application of such a voltage detection circuit is for purposes of over-current detection. Referring to FIG. 1C, for an IC being supplied from a DC source VDC, the supply current is made to pass through resistor Rsense. The voltage detection circuit measures the potential across the resistor Rsense via input terminals TI1 and TI2. The outputs of the voltage detection circuit, TO0 and TO1, are next sent to a sample and hold circuit where it is determined if over-current has occurred. If over-current has occurred, the sample and hold circuit will output a signal to open the switch S1, hence effectively disconnecting the DC source VDC to the IC.

As disclosed in U.S. Publication 2006/0113969, an example of such a voltage detection circuit is described. In the switch circuit, with reference to FIG. 1A, the resistor connection between the input voltage and the ground is reversed at different timing periods in order to implement offset element cancellation at the sampling circuit stage. In this example, during the first period, signal ‘a’ will close switches 01A, 02A, 03A and 04A simultaneously, and signal ‘b’ opens 01B, 02B, 03B and 04B simultaneously at the same time. Similarly, in the second period, signal ‘a’ will close switches 01B, 02B, 03B and 04B, and signal ‘b’ opens switches 01A, 02A, 03A and 04A simultaneously at the same time. First and second periods do not overlap with each other. A timing chart is as shown in FIG. 1B to illustrate the first and second periods' timing. During each period, the input voltages are halved by the resistor ratio to prevent any undesirable limitation due to insufficient dynamic range. By adding the output voltage difference of the switch circuit in the first period to the output voltage difference in the second period, which had its resistor connection reversed, offsets in terms of the relative error of the resistors in the switch circuit can be mutually cancelled.

However, in implementing the present invention using diffusion-type resistors, the method of reversing the resistor connection cannot be done simply. The first problem that needs to be taken into consideration is the biasing of the wells or isolation pockets containing the diffusion-type resistors, so as to prevent the occurrence of any parasitic diodes. The second problem that needs to be taken into consideration is that with non-ideal switches, it will be even more difficult to achieve high accuracy capability considering the addition of more switches due to the variation in the on-resistance of the switches under the influence of different conditions.

The present invention is intended to solve such problems, and it is an object of the present invention to provide switching means to implement offset element cancellation at the sampling circuit stage, as well as ensuring that no parasitic diodes result during that cancellation process.

### SUMMARY OF THE INVENTION

The purpose of this invention is to provide a method to solve the above problem so that high-accuracy voltage detection can be achieved, with the capability to allow offset cancellation in terms of relative error in its resistor divider network.

According to this invention, two switches are incorporated at the terminal of the well or isolation pocket containing the diffusion-type resistor to establish a connection to each side of the resistor's terminal. The switches are controlled sequentially such that the terminal of the well or isolation pocket is only connected to the side of the resistor terminal with higher voltage at any one time, while corresponding to the switching of the resistor divider network when it is reversed.

### BRIEF DESCRIPTION OF THE DRAWINGS

FIG. 1A is a circuit diagram of a switching voltage divider circuit based on prior art U.S. Publication 2006/0113969.

FIG. 1B is a Timing Chart showing signals ‘a’ and ‘b’ during first and second periods based on prior art of U.S. Publication 2006/0113969.

FIG. 1C is an exemplary system application using a voltage detection circuit.

FIG. 1D is an exemplary composition of Voltage Detection Circuit comprising a Digital Control Signal Block Circuit and Switching Voltage Divider Circuit.

FIG. 1E is a drawing illustrating an exemplary composition of Digital Control Signal Block Circuit and Switching Voltage Divider Circuit in a single IC.

FIG. 2A is a circuit diagram of a switching voltage divider circuit with switching resistor epi connection configuration.

FIG. 2B is a cross-sectional view of an exemplary diffusion-type resistor based on the present invention (case of a p-type diffusion contained in an n-type epi layer).

FIG. 2C is a cross-sectional view of another exemplary diffusion-type resistor based on the present invention (case of an n-type diffusion contained in a p-type epi layer).

FIG. 2D is a cross-sectional view of another exemplary diffusion-type resistor based on the present invention (case of a p-well resistor).

FIG. 2E is a cross-sectional view of another exemplary diffusion-type resistor based on the present invention (case of an n-well resistor).

FIG. 2F is a typical transmission gate.

FIG. 3 is the control signal waveform for the switch devices in the switching voltage divider circuit.

It will be recognized that some or all of the Figures are schematic representations for purposes of illustration and do not necessarily depict the actual relative sizes or locations of the elements shown.

### DETAILED DESCRIPTION OF THE PREFERRED EMBODIMENTS

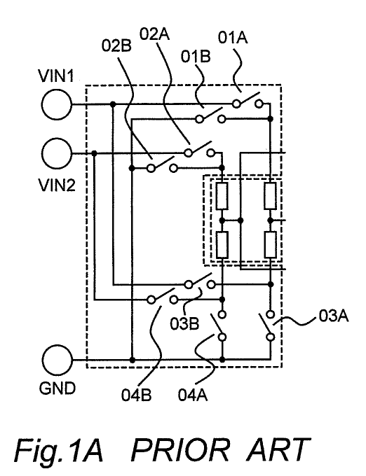

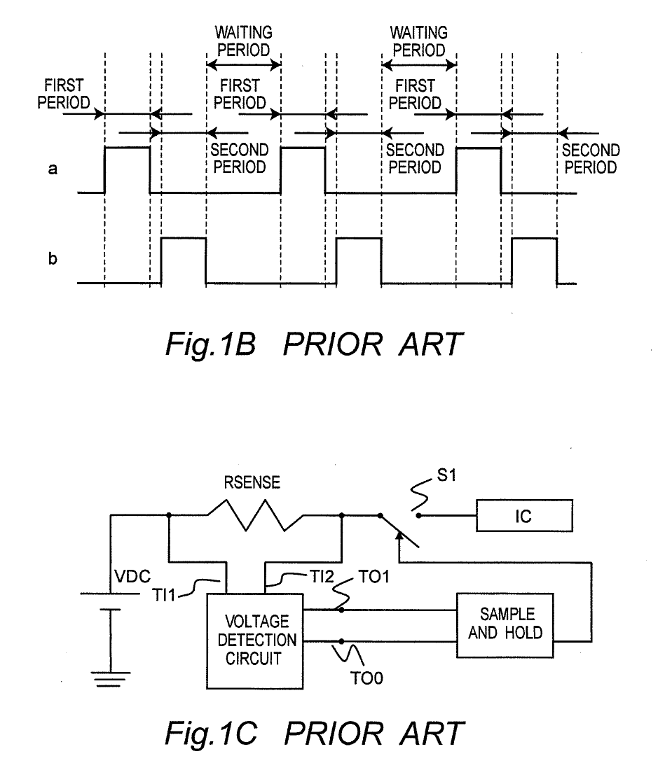

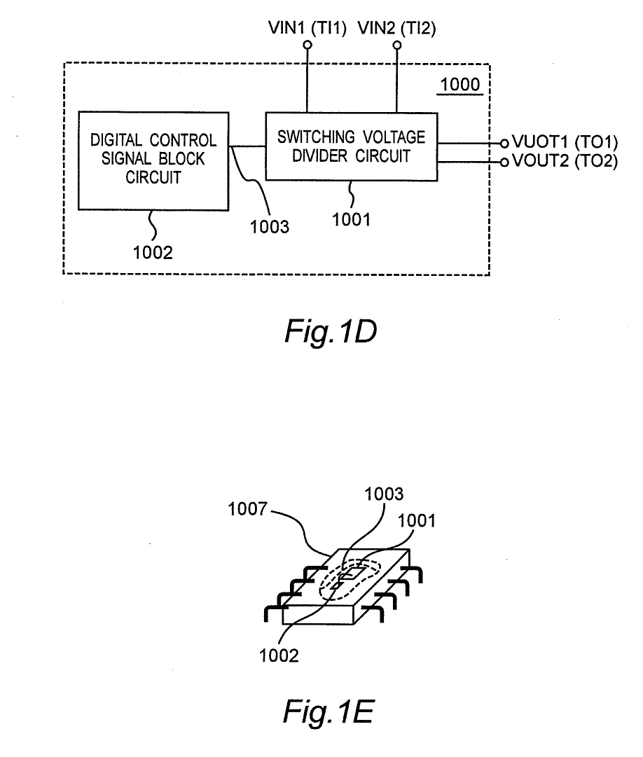

Referring to FIG. 1D, a first embodiment of the present invention has a voltage detection circuit 1000 which comprises a switching voltage divider circuit 1001 and a digital control signal block 1002. Control signals to the switching voltage divider circuit 1001 from digital control signal block 1002 are conveyed via electrical connection 1003. For this case, the switching voltage divider circuit 1001 and the digital control signal block 1002 make up a system. The voltage detection circuit 1000 is employed in the voltage detection circuit shown in FIG. 1C. The electrical connection 1003 is for second various ON and OFF signals to switches 11B, 12A, 13B, 14A, 15A, 16B, 17A and 18B, as well be explained later.

Referring to FIG. 1E, both the switching voltage divider circuit 1001 and digital control signal block 1002 may exist as 2 separate systems, but assembled within a single IC chip 1007. Control signals to the switching voltage divider circuit 1001 from digital control signal block 1002 are conveyed via electrical connection 1003.

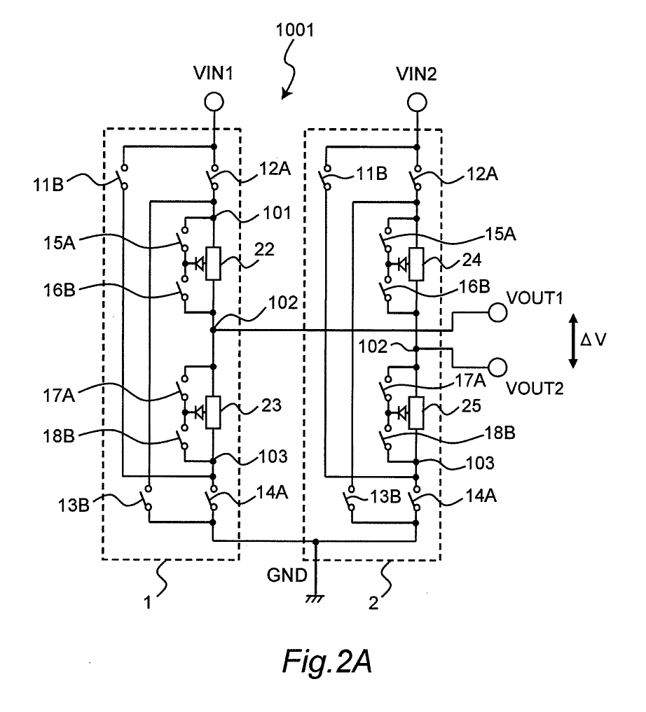

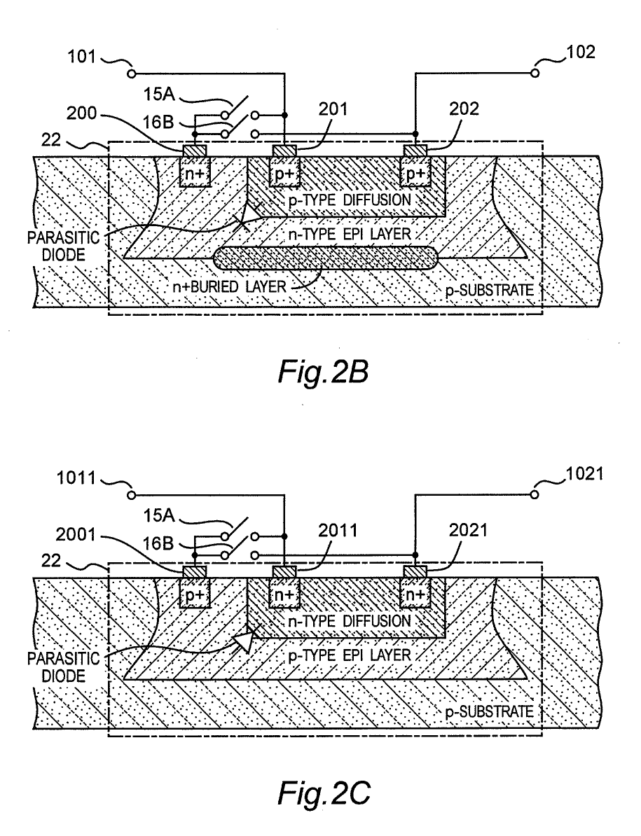

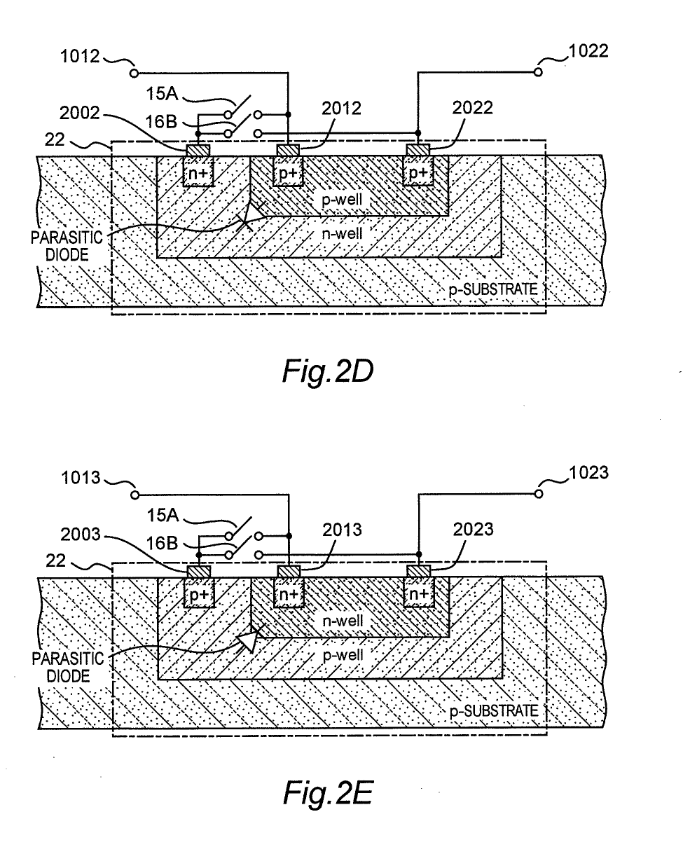

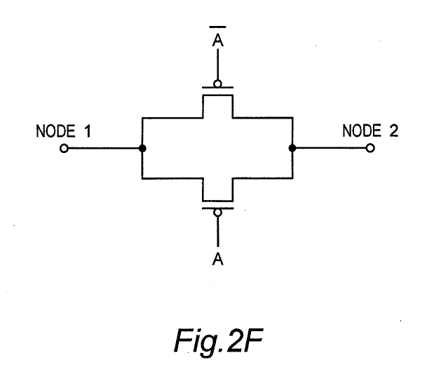

The switching voltage divider circuit 1001 is realized as shown in FIG. 2A.

The resistors used in the present invention are of the diffusion-type resistors. There are several types of diffusion-type resistors. Examples are the base-diffused resistors, where the resistor is in the form of a p-type (or n-type) diffusion contained in an n-type (or p-type) epitaxial (herein also referred to as epi) layer; p-well resistors, where the resistor is in the form of a p-well contained in an n-well further contained in a p-type epi layer or p-type substrate; n-well resistors, where the resistor is in the form of an n-well contained in a p-type epi layer or p-well.

For the following description, base-diffused resistors are used. Specifically, the case of a p-type diffusion contained in an n-type epi layer is described.

As shown in FIG. 2A, the switching voltage divider circuit 1001 has two input terminals VIN1 and VIN2, and a resistor divider network at each side of the input terminals, a resistor divider network 1 for input voltage VIN1 and a resistor divider network 2 for input voltage VIN2, to half the input voltages respectively.

The resistor divider network 1 has two same valued resistors 22 and 23 connected in series, four switch devices 11B, 12A, 13B and 14A which reverses the resistor divider network connection between the input terminal VIN1/VIN2 and ground at different timing period, and another four switch devices 15A, 16B, 17A and 18B which alternates the connection of the resistor N-well contact to one of the resistor contacts with the higher voltage at any particular point in time. A more detailed explanation of the contacts will be described later.

The resistor divider network 2 has two same valued resistors 24 and 25 connected in series. In the resistor divider network 2, switch devices are connected in the same manner as the switch devices connected in the resistor divider network 1.

Examples of switch devices that may be used are transmissions gates (as shown in FIG. 2F) and simple transistor switches. As transmission gates are well known, its operation will not be described here.

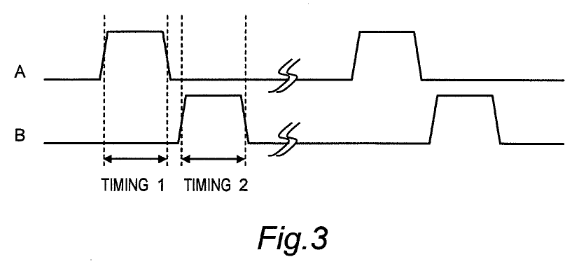

The switches in FIG. 2A are controlled in a sequential order with control signals shown in FIG. 3.

These control signals may be generated within the system, such as described before with reference to FIG. 1D; or may be obtained outside of the system in another system block within the same IC chip, such as described before with reference to FIG. 1E; or may be obtained externally (that is, outside of the IC chip in which the current system is located) via digital logic controllers, microprocessors, microcontrollers, or other means where such control signals may be derived from.

During Timing 1 as shown in FIG. 3, signal A is high and signal B is low, hence switches 12A, 14A, 15A and 17A are turned on while switches 11B, 13B, 16B and 18B are off. The operation is vice versa in Timing 2. Thus, signal A is low and signal B is high, hence inversing the state of the switches respectively. The on period of the switches in Timing 1 and Timing 2 must not be allowed to overlap as it will cause the input voltages VIN1/VIN2 to be shorted to GND.

Switch devices 12A and 14A serve as a first switch assembly for connecting the input terminal VIN1, the first diffusion type resistor 22, the second diffusion type resistor 23 and the ground terminal GND serially in said order. Switch devices 11B and 13B serve as a second switch assembly for connecting the ground terminal GND, the first diffusion type resistor 22, the second diffusion type resistor 23 and the input terminal VIN1 serially in said order.

FIG. 2B shows a cross-sectional view of an exemplary combination of the diffused resistor and switches as used in realizing the above mentioned resistor divider network. For the purpose of this description, a base-diffused resistor is used as an example. Specifically, a p-type diffusion contained in an n-type epi layer is used.

In particular, resistor 22 and switches 15A and 16B are described in this example. The n-type epi layer contact 200 is always connected to a potential that is high enough to prevent the conduction of the parasitic diode. Based on the present invention, n-type epi layer contact 200 is always connected to the higher of the two resistors' contact terminals' potentials, namely resistor contacts 201 and 202. The connections to either of the two contact potentials are made via switches 15A and 16B.

For example, when switch 15A is turned on, switches 12A and 14A are also turned on to provide high voltage from terminal VIN1 to terminal 101, so that in FIG. 2B a path 101, 15A, 200, n+, p+, 202, 102 is established to realize the reverse bias connection in diffusion type resistor 22. Similarly, when switch 16B is turned on, switch 11B and 13B are also turned on to provide high voltage from terminal VIN1 to terminal 102 via resistor 23, so that in FIG. 2B a path 102, 16B, 200, n+, p+, 201, 101 is established to realize the reverse bias connection in diffusion type resistor 22. Thus, switches 15A and 16B serve as a first control switch arrangement for connecting the first diffusion type resistor 22 in a reverse bias direction. Similarly, switches 17A and 18B serve as a second control switch arrangement for connecting the second diffusion type resistor 23 in a reverse bias direction. Thus, a voltage produced between the output terminals VOUT1 and VOUT2 of the first and second resistor divider networks 1 and 2, respectively, is accurately relative to a voltage applied between the input terminals VIN1 and VIN2 of the first and second resistor divider networks 1 and 2, respectively.

The switch 15A of the first control switch arrangement has its one end connected to epi contact segment 200 provided on resistor 22, and its other end connected to diffusion contact segment 201 provided on resistor 22. Similarly, switch 16B of the first control switch arrangement has its one end connected to epi contact segment 200 provided on resistor 22, and its other end connected to diffusion contact segment 202 provided on resistor 22. Diffusion contact segments 201 and 202 are separated, but provided on the same p-type diffusion area.

These switches are controlled via control signals. These may be generated within the system, as described before with reference to FIG. 1D; or may be obtained outside of the system in another system block within the same IC chip, as described before with reference to FIG. 1E; or may be obtained externally (that is, outside of the IC chip in which the current system is located) via digital logic controllers, microprocessors, microcontrollers, or other means where such control signals may be derived from.

The above mentioned exemplary resistor configuration is also applicable for a N-well type resistor in a P-well in an N-substrate. The only difference is that the switches will connect the P-well biasing to the lower of the two resistor contact terminals' potentials.

The above mentioned exemplary resistor configuration is also applicable for an n-type diffusion contained in a p-type epi layer, as shown in FIG. 2C. The only difference is that, to bias the p-type epi layer, the switches will connect the p-type epi layer contact 2001 to the lower of the two resistor contact terminals' potentials.

The n-type epi layer contact 200 of the p-type diffusion contained in an n-type epi layer, and the p-type epi layer contact 2001 of the n-type diffusion contained in a p-type epi layer may be referred to in general as the ‘epi contact’.

Similarly, the above mentioned exemplary resistor configuration is also applicable for a p-well resistor, as shown in FIG. 2D. The only difference is that, to bias the n-well, the switches will connect the n-well contact 2002 to the higher of the two resistor contact terminals' potentials.

Also, the above mentioned exemplary resistor configuration is also applicable for an n-well resistor, as shown in FIG. 2E. The only difference is that, to bias the p-well, the switches will connect the p-well contact 2003 to the lower of the two resistor contact terminals' potentials.

As described above, in general, besides the two contacts normally associated with a typical resistor, there is a third contact made to the diffusion immediately adjacent to the diffusion in which the resistors' terminals are connected to.

That is, for based diffused resistors, the third contact is the n-type epi layer contact 200 of the p-type diffusion contained in an n-type epi layer, and the p-type epi layer contact 2001 of the n-type diffusion contained in a p-type epi layer.

Also, for a p-well resistor the third contact is the n-well contact 2002.

As for n-well resistor, the third contact is the p-well contact 2003.

As we are referring to diffusion-type resistors, all 3 contacts may be generally referred to as diffusion contacts.

With reference to FIG. 2A, the operation of the present invention shall now be described. Again, for the purpose of this description, a base-diffused resistor is used as an example. Specifically, a p-type diffusion contained in an n-type epi layer is used.

In Timing 1 period, switches 11B, 13B, 16B and 18B are off as described earlier. At the same time, switch 12A and 14A will be closed to connect node 101 of resistor 22 to VIN1 and node 103 of resistor 23 to GND respectively. Switch 15A is also closed to connect the n-type epi layer contact 200 of resistor 22 to node 101 which is the side of resistor 22 that has a higher voltage compared to node 102, during this period. Similarly switch 17A is closed to connect the corresponding n-type epi layer contact of resistor 23 to node 102 which is the side of resistor 23 that has a higher voltage compared to node 103.

The same conditions are applied to resistor divider network 2 such that one end of the resistor divider network with resistor 24 is connected to VIN2 and the other end of the resistor divider network with resistor 25 is connected to GND. Correspondingly, the corresponding n-type epi layer contact of each resistor in network 2 is connected to its own resistor terminal with higher voltage.

During this period of Timing 1, VOUT1 terminal takes a voltage at node 102 of the resistor divider network 1 which is half the voltage of VIN1 including the relative error of the resistors 22 and 23, while VOUT2 terminal outputs a voltage at node 102 of the resistor divider network 2 which is half of VIN2 including the relative error of the resistors 24 and 25. The difference between VOUT1 and VOUT2, together with the respective relative errors, is stored by a sampling circuit in the following stage.

Next in Timing 2 period, the resistor divider network connections are reversed, with switches 12A, 14A, 15A and 17A being opened. On the other hand, switches 13B and 11B are now closed to connect node 101 of resistor 22 to GND and node 103 of resistor 23 to VIN1 respectively. Switch 16B is also closed to connect the epi-terminal of resistor 22 to node 102 which is the side of resistor 22 that has a higher voltage compared to node 101, during this period. Similarly switch 18B is closed to connect the epi-terminal of resistor 23 to node 103 which is the side of resistor 23 that has a higher voltage compared to node 102.

The same conditions are applied to resistor divider network 2 such that one end of the resistor divider network with resistor 24 is now connected to GND and the other end of the resistor divider network with resistor 25 is connected to VIN2. The epi-terminal of each resistor in network 2 is also switched accordingly so that it is connected to its own resistor terminal with higher voltage.

During this period of Timing 2 with the resistor divider network connections reversed, VOUT1 terminal again takes a voltage at node 102 of the resistor divider network 1 which is half the voltage of VIN1 including the relative error of resistors 22 and 23, while VOUT2 terminal outputs a voltage at node 102 of the resistor divider network 2 which is half of VIN2 including the relative errors of resistors 24 and 25. With that, the voltage difference between VOUT1 and VOUT2 in Timing 2 is now added to the voltage difference stored during Timing 1 by the sampling circuit. By summing the voltage difference between VOUT1 and VOUT2 in Timing 1 and the voltage difference in Timing 2, the relative errors of the resistors 22, 23, 24 and 25 can be mutually cancelled as demonstrated in the following example:

Let the resistance value of resistors 22, 23, 24 and 25 to be “R”, and the resistor 22 has a relative error “ΔR”, the voltage difference of the two output terminals during Timing 1, ΔV(1), is expressed as follows,

$$\begin{matrix}Δ V ( 1 ) = VOUT 1 ( 1 ) - VOUT 2 ( 1 ) \\ = VIN 1 / ( 2 + Δ R / R ) - VIN 2 / 2\end{matrix} \qquad ( 1 )$$

whereas in Timing 2, the voltage difference of the two output terminals, ΔV(2), is expressed as follows,

$$\begin{matrix}Δ V ( 2 ) = VOUT 1 ( 2 ) - VOUT 2 ( 2 ) \\ = VIN 1 [ ( 1 + Δ R / R ) / ( 2 + Δ R / R ) ] - VIN 2 / 2\end{matrix} \qquad ( 2 )$$

And the sum of the output voltage difference at both Timing 1 and 2 is as follows.

$$\begin{matrix}Δ V ( 1 ) + Δ V ( 2 ) = VIN 1 / ( 2 + Δ R / R ) - VIN 2 / 2 + \\ VIN 1 [ ( 1 + Δ R / R ) / ( 2 + Δ R / R ) ] - VIN 2 / 2 \\ = VIN 1 [ ( 2 + Δ R / R ) / ( 2 + Δ R / R ) ] - 2 ( VIN 2 / 2 ) \\ = VIN 1 - VIN 2\end{matrix} \qquad ( 3 )$$

As shown in equation (3), the resulting sum of the output voltage difference of the switch circuit at two different timing periods simply gives the actual voltage difference between the two input voltages VIN1 and VIN2 without the influence of the relative error in the resistors. The summing of the output voltage differences in Timings 1 and 2 can be achieved by using a sample-and-hold circuit which is able to retain the voltage difference in Timing 1, and subsequently adds it to the next voltage difference during Timing 2.

Correspondingly, the description of the operation above applies for other diffusion-type resistors as well.

For example and purpose of clarity, the following associations are described.

For the case of an n-type diffusion contained in a p-type epi layer (FIG. 2C), nodes 1011 and 1021, as well as contacts 2001, 2011 and 2021 correspond to nodes 101 and 102, as well as contacts 200, 201 and 202 of the p-type diffusion contained in an n-type epi layer.

For the case of a p-well resistor (FIG. 2D), nodes 1012 and 1022, as well as contacts 2002, 2012 and 2022 correspond to nodes 101 and 102, as well as contacts 200, 201 and 202 of the p-type diffusion contained in an n-type epi layer.

For the case of an n-well resistor (FIG. 2E), nodes 1013 and 1023, as well as contacts 2003, 2013 and 2023 correspond to nodes 101 and 102, as well as contacts 200, 201 and 202 of the p-type diffusion contained in an n-type epi layer.

Having described the above embodiment of the invention, various alternations, modifications or improvement could be made by those skilled in the art. Such alternations, modifications or improvement are intended to be within the spirit and scope of this invention. The above description is by ways of example only, and is not intended as limiting. The invention is only limited as defined in the following claims.

What is claimed is:

1. A switching voltage divider circuit, comprising:
two input terminals;
two resistor divider networks connected to each side of the input terminals; and
two output terminals that are fed to the next sampling circuit stage for further computation and processing.

2. The switching voltage divider circuit according to claim 1, wherein said resistor divider network comprises:
at least eight switch devices, having its turning on and off controlled by at least two control signals of non-overlapping timing periods;
two resistors, electrically connected in series so as to voltage-divide the potential of each of the said input terminals.

3. The switching voltage divider circuit according to claim 2, wherein said control signals are generated from within the system.

4. The switching voltage divider circuit according to claim 2, wherein said control signals are generated from outside of the system in another system block within the same IC chip.

5. The switching voltage divider circuit according to claim 2, wherein said control signals are generated from outside of the IC chip containing the switched voltage divider circuit.

6. The switching voltage divider circuit according to claim 2, wherein:
two of said switch devices are electrically connected to each of said resistors within the resistor divider network.

7. The switching voltage divider circuit according to claim 6, wherein said resistors are of the diffusion type resistors.

8. The switching voltage divider circuit according to claim 7, wherein said diffusion type resistors are base-diffused resistors.

9. The switching voltage divider circuit according to claim 8, wherein:
first terminal of a first switch device is electrically connected to the epi contact of a first of said resistors; and the second terminal of said first switch device is electrically connected to a first contact terminal of the first of said resistors; and
first terminal of a second switch device is electrically connected to the epi contact of the first of said resistors; and the second terminal of said second switch device is electrically connected to a second contact terminal of the first of said resistors
first terminal of a third switch device is electrically connected to the epi contact of a second of said resistors; and the second terminal of said third switch device is electrically connected to a first contact terminal of the second of said resistors; and
first terminal of a fourth switch device is electrically connected to the epi contact of the second of said resistors; and the second terminal of said fourth switch device is electrically connected to a second contact terminal of the second of said resistors.

10. The switching voltage divider circuit according to claim 7, wherein said diffusion type resistors are p-well resistors.

11. The switching voltage divider circuit according to claim 10, wherein:
first terminal of a first switch device is electrically connected to the n-well contact of a first of said resistors; and the second terminal of said first switch device is electrically connected to a first contact terminal of the first of said resistors; and
first terminal of a second switch device is electrically connected to the n-well contact of the first of said resistors; and the second terminal of said second switch device is electrically connected to a second contact terminal of the first of said resistors. first terminal of a third switch device is electrically connected to the n-well contact of a second of said resistors; and the second terminal of said third switch device is electrically connected to a first contact terminal of the second of said resistors; and
first terminal of a fourth switch device is electrically connected to the n-well contact of the second of said resistors; and the second terminal of said fourth switch device is electrically connected to a second contact terminal of the second of said resistors.

12. The switching voltage divider circuit according to claim 7, wherein said diffusion type resistors are n-well resistors.

13. The switching voltage divider circuit according to claim 12, wherein:
first terminal of a first switch device is electrically connected to the p-well contact of a first of said resistors; and the second terminal of said first switch device is electrically connected to a first contact terminal of the first of said resistors; and
first terminal of a second switch device is electrically connected to the p-well contact of the first of said resistors; and the second terminal of said second switch device is electrically connected to a second contact terminal of the first of said resistors. first terminal of a third switch device is electrically connected to the p-well contact of a second of said resistors; and the second terminal of said third switch device is electrically connected to a first contact terminal of the second of said resistors; and
first terminal of a fourth switch device is electrically connected to the p-well contact of the second of said resistors; and the second terminal of said fourth switch device is electrically connected to a second contact terminal of the second of said resistors.

14. The switching voltage divider circuit according to claim 1, wherein said resistors in the resistor divider network is a diffusion resistor type.

15. The switching voltage divider circuit according to claim 1, wherein said switch devices are transmission gates which are controlled via at least two control signals of non-overlapping timing periods.

16. The switching voltage divider circuit according to claim 1, wherein said switch devices are controlled by control signals generated from within the same IC chip.

17. A method for averaging two input voltages using a switched voltage divider circuit, the method comprising:
inputting a first input voltage to a first resistor divider network of a switched voltage divider circuit, hence being a first target to be averaged;
inputting a second input voltage to a second resistor divider network of the said switched voltage divider circuit, hence being a second target to be averaged;
controlling the switches in said first and second resistor divider networks so that a first group of switches are open simultaneously, while a second group of switches are closed simultaneously;
taking the difference between the first resistor-averaged signal output from said first resistor divider network, and the second resistor-averaged signal from said second resistor divider network, hence outputting this difference to the next stage.

18. A method for averaging two input voltages according to claim 17, wherein:
the said first group of switches are controlled by a first control signal; and
the said second group of switches are controlled by a second control signal.

19. A method for switching the diffusion contacts of diffusion-type resistors, the method comprising:
incorporating two switches, their first terminals connected to each side of the resistors' terminals, and the second terminals connected to the contact of the diffusion immediately adjacent to the diffusion in which said resistors' terminals are connected to;
turning on the first of said switches during a first period by a first control signal, while the second of said switches is turned off; and
turning on the second of said switches in the second period by the second control signal, while the first of said switches is turned off.

20. A method for switching the diffusion contacts of diffusion-type resistors according to claim 19, further comprising:
said switch devices will close so that the contact of the diffusion immediately adjacent to the diffusion in which said resistors' terminals are connected to is applied a voltage so as to ensure that the parasitic diode is turned off.

21. A method for switching the epi-contact of diffusion-type resistors according to claim 20, wherein said diffusion-type resistors are selected from the group consisting of base-diffused resistors, p-well resistors and n-well resistors.

22. A switching voltage divider circuit, comprising:
a first resistor divider network and a second resistor divider network, each resistor divider network comprising:
an input terminal;
a ground terminal;
an output terminal;
a first diffusion type resistor and a second diffusion type resistor connected in series with said output terminal being connected to a junction between said first and second diffusion type resistors;
a first switching assembly operative to connect said input terminal, said first diffusion type resistor, said second diffusion type resistor and said ground terminal serially in said order;
a second switching assembly operative to connect said ground terminal, said first diffusion type resistor, second diffusion type resistor and said input terminal serially in said order;
a first control switch arrangement operative to connect the first diffusion type resistor in a reverse bias direction; and
a second control switch arrangement operative to connect the second diffusion type resistor in a reverse bias direction,
whereby a voltage produced between the output terminals of the first and second resistor divider networks is accurately relative to a voltage applied between the input terminals of the first and second resistor divider networks.

23. The switching voltage divider circuit according to claim 22, wherein said first resistor divider network and said second resistor divider network have an identical structure.

24. The switching voltage divider circuit according to claim 22, wherein said diffusion type resistors are base-diffused resistors.

25. The switching voltage divider circuit according to claim 22, wherein said diffusion type resistors are p-well resistors.

26. The switching voltage divider circuit according to claim 22, wherein said diffusion type resistors are n-well resistors.

27. The switching voltage divider circuit according to claim 22,
wherein each diffusion type resistor has an epi contact segment, a first diffusion contact segment and a second diffusion contact segment, in which said epi contact segment is provided on an epi layer, and said first and second diffusion contact segments are provided separately on a diffusion layer, and
wherein said first control switch arrangement comprises:
a first switch device having one end connected to the epi contact segment of said first diffusion type resistor and the other end connected to said first diffusion contact segment of the same; and
a second switch device having one end connected to the epi contact segment of said first diffusion type resistor and the other end connected to said second diffusion contact segment of the same; and
wherein said second control switch arrangement comprises:
a third switch device having one end connected to the epi contact segment of said second diffusion type resistor and the other end connected to said first diffusion contact segment of the same; and
a fourth switch device having one end connected to the epi contact segment of said second diffusion type resistor and the other end connected to said second diffusion contact segment of the same.
